(19) United States
(12) Patent Application Publication
(10) Pub. No.: US 2025/0273520 A1
(43) Pub. Date: Aug. 28, 2025

(54) HOUSING, SEMICONDUCTOR MODULE HAVING A HOUSING, AND METHOD FOR ASSEMBLING A SEMICONDUCTOR MODULE

(71) Applicant: Infineon Technologies AG, Neubiberg (DE)

(72) Inventors: Tobias Ricken, Lippstadt (DE); Roman Lennart Tschirbs, Soest (DE)

(21) Appl. No.: 19/059,963

(22) Filed: Feb. 21, 2025

(30) Foreign Application Priority Data
Feb. 23, 2024 (DE) 102024105152.3

(51) Int. Cl. H01L 23/053; H01L 21/48; H01L 23/00; H01L 23/08; H01L 23/10; H01L 23/14; H01L 23/498; H01L 23/538

(52) U.S. Cl. CPC H01L 23/053; H01L 21/4803; H01L 23/08; H01L 23/10; H01L 23/142; H01L 23/49811; H01L 23/5383; H01L 24/32; H01L 24/48; H01L 24/73; H01L 2224/32225; H01L 2224/48225; H01L 2224/73265; H01L 2924/1815

(57) ABSTRACT

A housing for a semiconductor module includes sidewalls and two or more cantilever elements integrally formed with or attached to the sidewalls. Each of the two or more cantilever elements includes at least one cantilever arm having a free end, and a protrusion formed at the free end of each of the at least one cantilever arm. Each of the two or more cantilever elements is configured to form a snap-fit connection with a corresponding counterpart formed in a base plate of the semiconductor module.

### TECHNICAL FIELD

The instant disclosure relates to a housing, a semiconductor module comprising a housing, and a method for assembling a semiconductor module.

### BACKGROUND

Power semiconductor module arrangements often include at least one substrate arranged in a housing. A semiconductor arrangement including a plurality of controllable semiconductor elements (e.g., two IGBTs in a half-bridge configuration) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may be attached to a base plate. The housing may be glued to the base plate such that the base plate forms a ground surface of the housing. When gluing the housing to the substrate, however, the housing needs to be secured in a desired position until the glue that is used to glue the housing to the substrate is sufficiently hardened and a stable connection has been formed. This generally requires an additional fixation step, as well as additional components such as, e.g., screws. Each additional component increases the overall cost, and each additional step during the assembly process requires additional process time and further increases the overall cost of the power semiconductor module arrangement.

There is a need for a housing and a power semiconductor module arrangement comprising a housing that may be assembled in an effective and cost-efficient way.

### SUMMARY

A housing for a semiconductor module includes sidewalls, and two or more cantilever elements integrally formed with or attached to the sidewalls, wherein each of the two or more cantilever elements includes at least one cantilever arm having a free end, and a protrusion formed at the free end of each of the at least one cantilever arm, and each of the two or more cantilever elements is configured to form a snap-fit connection with a corresponding counterpart formed in a base plate of the semiconductor module.

A semiconductor module includes a housing and a base plate, wherein the base plate includes a corresponding counterpart for each of the one or more cantilever elements, and each of the one or more cantilever elements is inserted into a different one of the counterparts.

A method for assembling a semiconductor module includes arranging a housing on a base plate of the semiconductor module, wherein arranging the housing on the base plate includes inserting each of the one or more cantilever elements into a different one of corresponding counterparts provided by the base plate.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module in which the housing is glued to a base plate.

FIGS. 2A to 2C are cross-sectional views of a sidewall of a housing according to embodiments of the disclosure while being mounted to a base plate.

FIG. 3 is a cross-sectional view of a housing mounted to a base plate according to further embodiments of the disclosure.

FIG. 4 schematically illustrates a three-dimensional view of a cantilever element according to embodiments of the disclosure.

FIG. 5 schematically illustrates a cross-sectional view of a housing mounted to a base plate according to further embodiments of the disclosure.

FIG. 6 schematically illustrates three-dimensional views of cantilever elements according to further embodiments of the disclosure.

FIG. 7 schematically illustrates a cross-sectional view of a housing mounted to a base plate according to further embodiments of the disclosure.

FIG. 8 schematically illustrates a cross-sectional view of a housing mounted to a base plate according to even further embodiments of the disclosure.

FIG. 9 schematically illustrates a cross-sectional view of a housing mounted to a base plate according to even further embodiments of the disclosure.

FIG. 10 schematically illustrates a cross-sectional view of a housing mounted to a base plate according to even further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

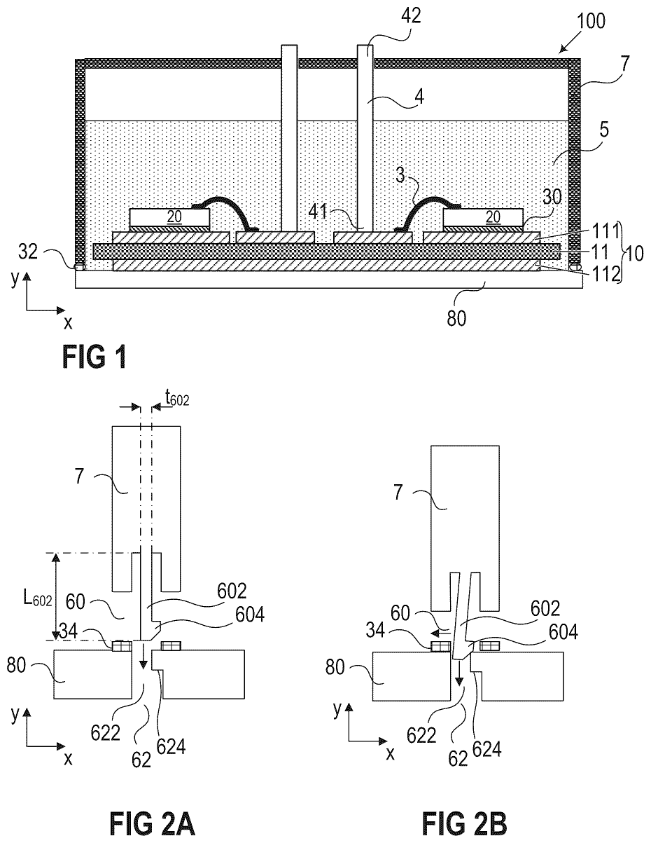

Referring to FIG. 1, a cross-sectional view of a semiconductor module 100 is illustrated. The semiconductor module 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 80 which forms a base surface of the housing 7, while the housing 7 itself solely comprises sidewalls and a cover. In some power semiconductor module arrangements 100, more than one substrate 10 is arranged within the same housing 7. The cover of the housing 7 is generally optional and may also be omitted.

One or more semiconductor bodies 20 may be arranged on the substrate 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes four different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The semiconductor module 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second end 42. The terminal elements 4 illustrated in FIG. 1, however, are only examples. Terminal elements 4 may be implemented in any other way and may be arranged at any other position. For example, one or more terminal elements 4 may be arranged close to or adjacent to the sidewalls of the housing 7. Any other suitable implementation is possible. The terminal elements 4 may consist of or include a metal such as copper, aluminum, gold, silver, or any alloys thereof, for example. The terminal elements 4 may be electrically and mechanically connected to the substrate 10 by an electrically conductive connection layer (not specifically illustrated for the terminal elements 4). Such an electrically conductive connection layer generally may be a solder layer, a layer of an electrically conductive adhesive, or a layer of a sintered metal powder, e.g., a sintered silver powder, for example. According to other examples, terminal elements 4 may be inserted into hollow sleeves which are attached to the substrate 10 (sleeves not specifically illustrated in FIG. 1).

Conventional semiconductor modules 100 generally further include an encapsulant or casting compound 5. The casting compound 5 may consist of or include a cured silicone gel or may be a rigid molding compound, for example. The casting compound 5 may at least partly fill the interior of the housing 7, thereby covering the components and electrical connections that are arranged on the substrate 10. The terminal elements 4 may be partly embedded in the casting compound 5. At least their second ends 42, however, are not covered by the casting compound 5 and protrude from the casting compound 5 through the housing 7, to the outside of the housing 7. The casting compound 5 is configured to protect the components and electrical connections inside the semiconductor module 100, in particular inside the housing 7, from certain environmental conditions and mechanical damage.

The semiconductor module 100 further comprises a base plate 80. One or more substrates 10 may be arranged on the base plate 80. The housing 7 is arranged on the base plate 80 such that the base plate 80 forms a bottom of the housing 7. The housing 7 may be glued to the base plate 80 in order to remain in a desired position with respect to the base plate 80. A glued joint 32 (layer of glue) between the housing 7 and the base plate 80 is often sufficient to hold the housing 7 in its desired position with regard to the base plate 80. The glued joint 32 further seals the housing 7 such that the material that is used to form the casting compound 5 does not leak out of the housing 7 before it is sufficiently hardened (cured). When gluing the housing 7 to the base plate 80, however, the housing 7 needs to be secured in a desired position until the glue that is used to glue the housing 7 to the base plate 80 is sufficiently hardened and a stable connection (adhesive joint) has been formed. This generally requires an additional fixation step, as well as additional components such as, e.g., screws. Each additional component increases the overall cost, and each additional step during the assembly process requires additional process time and further increases the overall cost of the power semiconductor module arrangement.

A housing 7 according to embodiments of the disclosure therefore comprises sidewalls and two or more cantilever elements 60 integrally formed with or attached to the sidewalls. Each of the two or more cantilever elements 60 comprises at least one cantilever arm 602 having a free end, and a protrusion 604 formed at the free end of each of the at least one cantilever arm 602. Each of the two or more cantilever elements 60 is configured to form a snap-fit connection with a corresponding counterpart 62 formed in a base plate 80 of the semiconductor module 100.

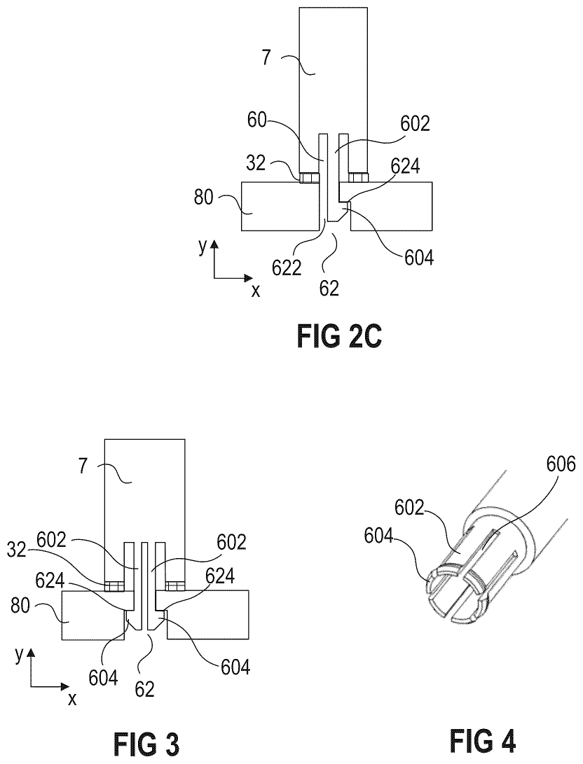

Now referring to FIGS. 2A to 2C, a section of a housing 7 that is mounted to a base plate 80 is schematically illustrated. The sidewalls of the housing 7, when the housing 7 is mounted on the base plate 80, generally extend in a vertical direction y that is perpendicular to a top surface of the base plate 80. The top surface of the base plate 80 is a surface the one or more substrate s 10 are mounted on. The cantilever elements 60 also extend in the vertical direction y. In particular, the cantilever arm 602 may extend in the vertical direction y. The sidewalls generally comprise a lower end and an upper end, wherein the sidewalls are configured to be mounted to the base plate 80 of the semiconductor module 100 such that the lower end of the sidewalls faces towards the base plate 80. A cover of the housing 7 may be mounted to the upper end of the sidewalls, for example, in order to close the housing 7. A cover, however, is generally optional. The two or more cantilever elements 60 extend beyond the lower end of the sidewalls, as is schematically illustrated in FIGS. 2A to 2C. FIG. 2A schematically illustrates the housing 7 and the base plate 80 in an unmounted state, FIG. 2B schematically illustrates the housing 7 while being mounted to the base plate 80, and FIG. 2C schematically illustrates the housing 7 and the base plate 80 in a mounted state. When mounting the housing 7 to the base plate 80, the cantilever element 60 is inserted in a corresponding counterpart 62 provided in the base plate 80. For example, the counterpart 62 may be formed by a simple through hole 622 formed in the base plate 80. The through hole 622 may have a round cross-section, for example. Any other suitable cross-section, however, is generally also possible. The cantilever element 60, when being inserted into the counterpart 62, is moved out of its resting position (horizontally, i.e. in a horizontal direction x), as is schematically illustrated in FIG. 2B. Once the housing 7 is in a desired position with respect to the base plate 80, the cantilever arm 602 (i.e. the protrusion 604) snaps into the counterpart 62, thereby fixating the housing 7 in a desired position with respect to the base plate 80.

The snap-fit connection formed between the cantilever element 60 and its corresponding counterpart 62 cannot be easily detached. The snap-fit connection formed between the housing 7 and the base plate 80 is not a very stable connection, and, in many cases, would not endure the entire lifetime of the semiconductor module 100. This, however, is not required. The snap-fit connection is merely required to hold the housing 7 in its desired position with respect to the base plate 80 until a glued joint has been formed between the housing 7 and the base plate 80. This is also schematically illustrated in FIGS. 2A to 2C. In FIG. 2A, an adhesive layer 34 is formed on the base plate 80. Alternatively, the adhesive layer 34 could also be formed on the lower end of the sidewalls of the housing 7 instead. The housing 7 is then arranged on the base plate 80 such that the adhesive layer 34 is arranged between the sidewalls of the housing 7 and the base plate 80, and the housing 7 is secured to the base plate 80 by means of the snap-fit connection. A curing step may then follow, during which the adhesive layer 34 is cured, thereby forming a glued joint 32 (permanent connection) between the housing 7 and the base plate 80. Once the glued joint 32 has been formed, the housing 7 is primarily held in its desired position with respect to the base plate 80 by means of the glued joint 32.

A housing 7 for a semiconductor module 100 usually has a rectangular or square cross-section. That is, a housing 7 usually comprises four sidewalls. Any other cross-section and any other number of sidewalls, however, is generally possible. A housing 7 may comprise two cantilever elements 60. Two cantilever elements 60 may be arranged on opposite sides of the housing 7, for example. This may generally be sufficient to hold the housing 7 in a desired position with respect to the base plate 80 until the glued joint 32 has been formed. A housing 7, however, may also comprise more than two cantilever elements 60. The number of cantilever elements 60 may depend on a size of the housing 7, for example. According to one example, cantilever elements 60 are arranged in regular intervals along the sidewalls of the housing 7. A distance between two directly subsequent cantilever elements 60 may be 15 millimeters, or more, for example.

Each of the two or more cantilever elements 60 comprises at least one cantilever arm 602 having a free end, and a protrusion 604 formed at the free end of each of the at least one cantilever arm 602. The protrusion 604 may form a barb such that it cannot move back out of the counterpart 62, once it has been inserted. The protrusion 604 may further comprise a chamfered surface which allows to easily insert it into the counterpart 62. A cantilever element 60 comprising a single cantilever arm 602 is schematically illustrated in FIGS. 2A to 2C. The cantilever arm 602 may be comparably thin. That is, a thickness t₆₀₂ of the cantilever arm 602 may be between 0.4 and 2.0 millimeters, for example. A length L₆₀₂ of the cantilever arm 602 may be between 5 and 15 millimeters, for example. In this way, the cantilever arm 602 is flexible enough such that it can bend out of its resting position when being inserted into the respective counterpart 62. A cantilever element 60 comprising exactly one cantilever arm 602, however, is only an example.

Referring to FIG. 3, a cantilever element 60 may comprise two cantilever arms 602 which, when inserted into the respective counterpart 62, bend toward each other. Any other number of cantilever arms 602, however, is also possible. Now referring to FIG. 4, a cantilever element 60 according to embodiments of the disclosure is schematically illustrated. In this example, the cantilever element 60 comprises a hollow cylinder with two or more slits 606 formed therein, wherein the two or more slits 606 separate the cantilever arms 602 from each other. In the example illustrated in FIG. 4, the hollow cylinder has six slits 606 formed therein, resulting in six cantilever arms 602. A hollow cylinder is generally easy to manufacture. For example, a hollow cylinder can be easily manufactured by means of an injection molding processes. The slits 606 may either be formed by arranging respective protrusions in a mold. It is, however, also possible that a continuous hollow cylinder is formed first without any slits, and the slits 606 are subsequently formed in the hollow cylinder, e.g., by means of stamping or machining techniques. FIG. 6 schematically illustrates hollow cylinders having three slits, A), and six slits, B), C). The hollow cylinder of example C) is shorter than the hollow cylinder of examples A) and B).

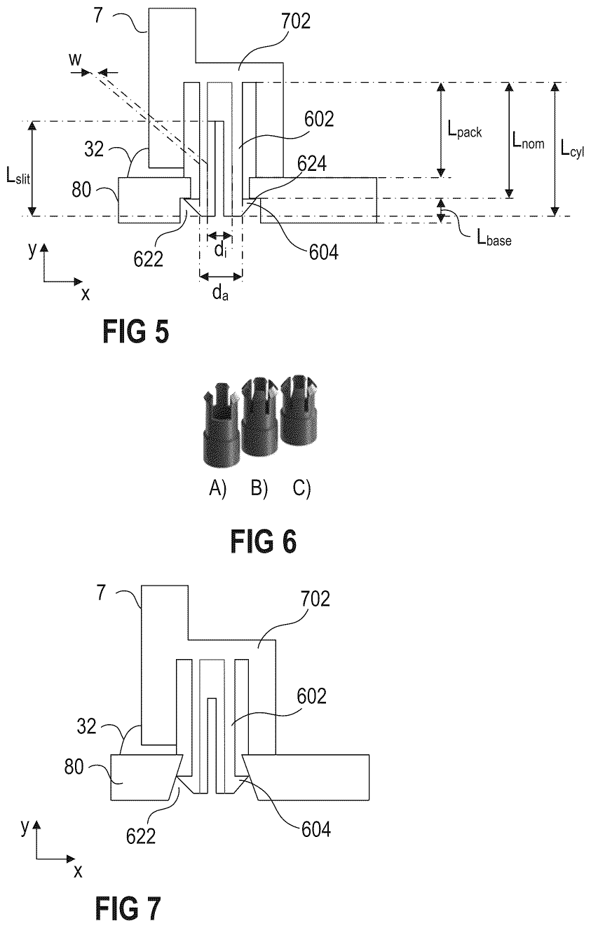

Referring to FIG. 5, a hollow cylinder may have an inner diameter dᵢ of between 2.0 and 14.6 millimeters, and an outer diameter dₐ of between 4.0 and 15.0 millimeters, wherein a difference between the inner diameter di and the outer diameter da defines a wall thickness w of the hollow cylinder. The wall thickness w may be between 0.4 and 2 millimeters, for example. The hollow cylinder may have an overall length L_{cyl} of between 6 and 16 millimeters, for example. The overall length L_{cyl} of the hollow cylinder extends in the vertical direction y, perpendicular to the base plate 80, when the housing 7 is arranged on the base plate 80. A length Lₛₗᵢₜ of each of the two or more slits 606 formed in the hollow cylinder (in the vertical direction y) may be between 0.5 and 8 millimeters, for example.

The hollow cylinder may be partly arranged in a cavity provided in the housing 7. As is schematically illustrated in FIG. 5, for example, the housing 7 may comprise at least one protrusion 702 extending from and perpendicular to the sidewalls of the housing 7. Each of the one or more cantilever elements 60 may be attached to one of the at least one protrusion 702. In the example illustrated in FIG. 5, the protrusion forms a cavity, and the cantilever element 60 (e.g., the hollow cylinder) is partly arranged in the cavity. In order to be able to form a snap-fit connection between the cantilever element 60 and the corresponding counterpart 62 in the base plate 80, the cantilever element 60 extends beyond the lower end of the sidewalls. That is, the cantilever element 60 at least partly protrudes out of the cavity provided by the protrusion 702.

When the snap-fit connection has been formed, a first section of the cantilever element 60 is arranged within the counterpart 62 formed in the base plate 80, and a second section of the cantilever element 60 may be arranged outside of the counterpart 62. A length L_{pack} of the second section may be between 0 (zero) and 44 millimeters, for example. That is, in some cases, the entire cantilever element 60 may be arranged in the corresponding counterpart 62.

The counterpart 62 may be formed by a through hole extending through the base plate 80. In the examples illustrated in FIGS. 2A-2C, 3 and 5, the through hole 622 has a first width or diameter in a first section, and a second width or diameter that is greater than the first width or diameter in a second section such that a protrusion 624 is formed within the through hole 622. The first section is formed adjacent to the top surface of the base plate 80, and the second section is formed between the first section and a lower surface of the base plate 80, opposite the top surface. The first width or diameter of the first section may be chosen such that the cantilever arms 602 are slightly moved out of their resting position when the cantilever element 60 is inserted into the counterpart 62.

A base plate 80 may have a thickness in the vertical direction y of between 3and 5 millimeters. The first section of a through hole 622 may have a thickness of between 0 (zero) and about 1 millimeter, for example. In typical base plates 80, a thickness L_{base} of the second section may be between 1.5 and 2 millimeters, for example. When the cantilever element 60 is inserted into the counterpart 62, the protrusion(s) 604 first pass through the first section, having the smaller width or diameter. The cantilever arm(s) 602 are bent out of a resting position when the protrusion(s) 604 pass through the first section of the through hole 622. When the protrusion(s) 604 reach the second section having the larger width or diameter, the cantilever arm(s) 602 will snap back into their resting position(s), and the protrusion(s) 604 of the cantilever element 60 as well as the protrusion 624 provided in the through hole 622 prevent the cantilever element 60 from moving back out of the counterpart 62. When the snap-fit connection is formed between the two or more cantilever elements 60 and the respective counterparts 62, the housing 7 is slightly pressed on the adhesive layer 34 arranged between the housing 7 and the base plate 80. A nominal length Lₙₒₘ of the cantilever element 60 is the overall length L_{cyl} of the cantilever element 60 minus a length of the protrusion 604. The nominal length Lₙₒₘ may be between 2 and 45 millimeters, e.g., between 5 and 15 millimeters.

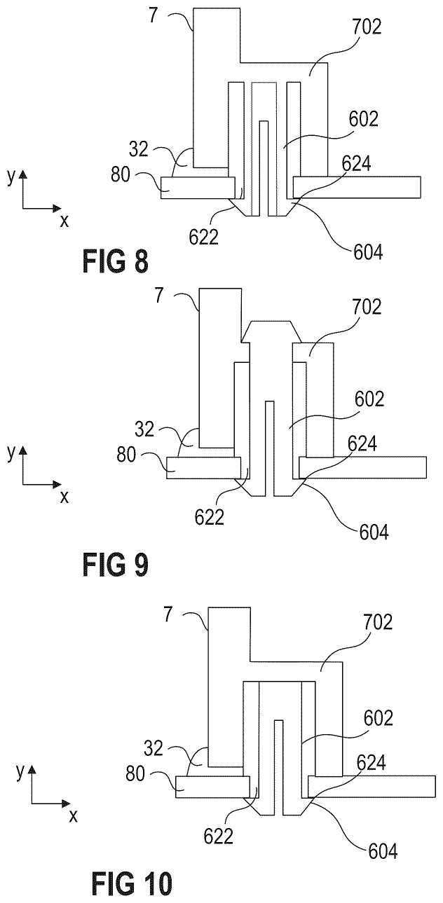

The counterpart 62 may be implemented in different ways. As has been described above, the counterpart 62 may be formed by means of a through hole 622 having different widths or diameters, thereby forming a protrusion 624 that prevents the protrusion 604 of the cantilever element 60 from moving back out of the through hole 622 again. Referring to FIG. 7, in an alternative embodiment the counterpart 62 comprises a through hole 622 formed in the base plate 80, wherein a width or diameter of the through hole 622 gradually increases from a first surface of the base plate 80 towards a second surface of the base plate 80 opposite the first surface. Alternatively, it is even possible that the counterpart 62 is formed by a through hole having a uniform width or diameter. This is schematically illustrated in FIG. 8. In this case, the protrusion 604 of the cantilever element 60 may be pushed through the entire base plate 80 until it is arranged on an opposite side of the base plate 80. The base plate 80 itself then prevents the protrusion 604 of the cantilever element 60 from moving back out of the through hole 622.

The two or more cantilever elements 60 may be integrally formed with the housing 7, i.e. with the sidewalls of the housing 7. That is, the two or more cantilever elements 60 may consist of the same material as the housing 7. This is schematically illustrated in FIG. 8, for example. It is, however, also possible that the two or more cantilever elements 60 are formed as separate components and are attached to the housing 7 in any suitable way. Referring to FIG. 9, a through hole may be provided in a protrusion 702 extending from the housing 7, and a cantilever element 60 may extend through the through hole. According to another example, and as is schematically illustrated in FIG. 10, the cantilever element 60 may even be formed by means of a so-called 2K injection molding process. That is, the cantilever element 60 may consist of a first plastic material, and the sidewalls of the housing 7 may consist of a material that differs from the first plastic material. 2K injection molding processes are generally known and will not be described in further detail herein. The cantilever elements 60 may consist of a material having the same or at least a similar elastic modulus as the material the housing 7 consists of. The material that is used to form the cantilever elements 60, however, may be more flexible (e.g., more rubber like) than the material of the housing 7, such that it may easily be inserted into the counterpart 62 (sufficient flexibility of the cantilever arms 602).

When a housing 7 comprising two or more cantilever elements 60 is arranged on the base plate 80 of a semiconductor module, the snap-fit connections between the cantilever elements 60 and the corresponding counterparts 62 formed in the base plate 80 are formed simultaneously. That is, no additional process steps are required to fix the housing 7 on the base plate 80 until the adhesive layer 34 has been cured and the housing 7 is securely attached to the base plate 80 by means of a glued joint 32. A semiconductor module 100 comprising a housing 7 according to embodiments of the disclosure, therefore, may be easily assembled, and the overall number of process steps is reduced as compared to semiconductor modules comprising conventional housings.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A housing for a semiconductor module, the housing comprising:
sidewalls; and
two or more cantilever elements integrally formed with or attached to the sidewalls,
wherein each of the two or more cantilever elements comprises at least one cantilever arm having a free end and a protrusion formed at the free end,
wherein each of the two or more cantilever elements is configured to form a snap-fit connection with a corresponding counterpart formed in a base plate of the semiconductor module.

2. The housing of claim 1, wherein the sidewalls comprise a lower end and an upper end, wherein the sidewalls are configured to be mounted to the base plate of the semiconductor module such that the lower end of the sidewalls faces towards the base plate, and wherein the two or more cantilever elements extend beyond the lower end of the sidewalls.

3. The housing of claim 1, wherein each cantilever element comprises a hollow cylinder with two or more slits formed therein, and wherein the two or more slits separate the cantilever arms from each other.

4. The housing of claim 3, wherein the hollow cylinder has an inner diameter of between 2.0 and 14.6 millimeters, and an outer diameter of between 4.0 and 15.0 millimeters, wherein a difference between the inner diameter and the outer diameter defines a wall thickness of the hollow cylinder, and wherein the wall thickness is between 0.4 and 2 millimeters.

5. The housing of claim 3, wherein the hollow cylinder has an overall length of between 6 and 16 millimeters.

6. The housing of claim 3, wherein a length of each of the two or more slits formed in the hollow cylinder is between 0.5 and 8 millimeters.

7. The housing of claim 1, further comprising:
at least one protrusion extending from and perpendicular to the sidewalls,
wherein each of the one or more cantilever elements is attached to one of the at least one protrusion.

8. The housing of claim 1, wherein the one or more cantilever elements consist of a first plastic material.

9. The housing of claim 8, wherein the sidewalls consist of a material that differs from the first plastic material.

10. A semiconductor module, comprising:
a housing comprising sidewalls and two or more cantilever elements integrally formed with or attached to the sidewalls, wherein each of the two or more cantilever elements comprises at least one cantilever arm having a free end and a protrusion formed at the free end; and
a base plate comprising a corresponding counterpart for each of the two or more cantilever elements,
wherein each of the two or more cantilever elements is inserted into a different one of the counterparts.

11. The semiconductor module of claim 10, further comprising a glued joint arranged between the housing and the base plate.

12. The semiconductor module of claim 10, wherein each of the counterparts comprises a through hole extending through the base plate, wherein:
the through hole has a uniform width or diameter;
the through hole has a first width or diameter in a first section, and a second width or diameter that is greater than the first width or diameter in a second section such that a protrusion is formed within the through hole; or the through hole has a width or diameter that gradually increases from a first surface of the base plate towards a second surface of the base plate opposite the first surface.

13. A method for assembling a semiconductor module, the method comprising:
arranging a housing on a base plate, wherein the housing comprises sidewalls and two or more cantilever elements integrally formed with or attached to the sidewalls, each of the two or more cantilever elements comprising at least one cantilever arm having a free end and a protrusion formed at the free end, wherein the base plate comprises a corresponding counterpart for each of the two or more cantilever elements,
wherein arranging the housing on the base plate comprises inserting each of the two or more cantilever elements into a different one of corresponding counterparts provided by the base plate.

14. The method of claim 13, further comprising:
forming an adhesive layer on the base plate or on a lower end of the sidewalls of the housing prior to arranging the housing on the base plate; and
curing the adhesive layer after arranging the housing on the base plate, thereby forming a glued joint between the housing and the base plate.
